(19) United States
(12) Patent Application Publication
(10) Pub. No.: US 2024/0178633 A1
(43) Pub. Date: May 30, 2024

(54) LASER DIODE PACKAGE

(71) Applicant: EOL CO., LTD, Gwangju (KR)

(72) Inventors: Su Hyun Kim, Gwangju (KR); Dai Hyoung Koo, Gwangju (KR); Gi Hwan Myeong, Gwangju (KR)

(73) Assignee: EOL CO., LTD, Gwangju (KR)

(21) Appl. No.: 18/505,528

(22) Filed: Nov. 9, 2023

(30) Foreign Application Priority Data
Nov. 24, 2022 (KR) 10-2022-0158991

(51) Int. Cl. H01S 5/024; H01S 5/02218; H01S 5/02253; H01S 5/40

(52) U.S. Cl. CPC H01S 5/02423; H01S 5/02218; H01S 5/02253; H01S 5/4012; H01S 5/4075

(57) ABSTRACT

A laser diode package according to the present disclosure includes a packaging housing unit and a coolant housing unit, wherein the coolant housing unit is coupled to the packaging housing unit, includes a coolant inlet through which coolant is introduced and a coolant outlet through which the coolant is discharged, and has a coolant flow path therein, and laser light source units disposed on a base of the packaging housing unit and each including a laser diode configured to emit a laser beam, wherein the laser light source unit includes a cooler coupled to the base, including a coolant channel connected to the coolant flow path of the coolant housing unit, and having at least an upper surface made of a metal layer, and a submount bonding-coupled to the upper surface of the cooler and having an upper surface to which the laser diode is bonding-coupled.

### CROSS-REFERENCE TO RELATED APPLICATION

This application claims priority to and the benefit of Korean Patent Application No. 2022-0158991, filed on Nov. 24, 2022, the disclosure of which is incorporated herein by reference in its entirety.

### BACKGROUND

### 1. Field of the Invention

The present disclosure relates to a laser diode package, and more particularly, to a laser diode package having a mounting structure capable of effectively dissipating heat of a laser diode.

### 2. Discussion of Related Art

Laser light sources, such as laser diodes, are used in various applications, such as laser welding, laser soldering, or as a laser pumping source, due to the advantage of being coupled to optical fibers to easily and efficiently transmit a laser beam to a desired point.

The power of a laser beam emitted from a single laser diode is limited, and thus, a laser diode package that combines a plurality of laser diodes is commonly used. The laser diode package is generally configured to condense laser beams output from 20 to 40 laser diode chips to output a high-power laser beam. In recent years, the number of laser diode chips included in the laser diode package has gradually increased as the power of the laser beam required in industrial applications has increased.

As described above, with the increasing power of the laser diode package, heat management to ensure performance and lifetime becomes an important factor in packaging technology.

### SUMMARY OF THE INVENTION

The present disclosure is directed to providing a laser diode package having a laser diode mounting structure capable of effectively dissipating heat of a laser diode.

A laser diode package according to the present disclosure includes a packaging housing unit and a coolant housing unit. The coolant housing unit is coupled to the packaging housing unit, includes a coolant inlet through which coolant is introduced and a coolant outlet through which coolant is discharged, and has a coolant flow path therein. On a base of the packaging housing unit, laser light source units each including a laser diode configured to emit a laser beam, collimating lenses each configured to collimate the laser beam emitted from the laser light source unit, reflective mirrors each configured to reflect the collimated laser beam to an optical element arrangement region on the base, and an optical fiber provided in the optical element arrangement region and in which a stacked beam formed by gathering each laser beam is coupled and emitted to the outside are disposed. The laser light source unit may include a cooler coupled to the base, including a coolant channel connected to the coolant flow path of the coolant housing unit, and having at least an upper surface made of a metal layer, and a submount bonding-coupled to the upper surface of the cooler and having an upper surface to which the laser diode is bonding-coupled.

According to an embodiment of the present disclosure, the base of the packaging housing unit may be divided into a step-type surface having a plurality of stepped surfaces, and the optical element arrangement region formed at one side of the step-type surface, the laser light source units may be disposed on the stepped surfaces of the step-type surface, respectively, in a direction facing each other, and include the laser light source units disposed along one side surface of the base to form a first row and the laser light source units disposed along the other side surface of the base to form a second row, in a space between the laser light source unit of the first row and the laser light source unit of the second row, a slow-axis collimating (SAC) lens for collimating the laser beam emitted from each laser light source unit and the reflective mirror may be installed in each stepped surface, and the optical element arrangement region may include a beam combiner configured to combine a first beam stack, in which laser beams from the laser light source units of the first row are aligned in a height direction, and a second beam stack, in which laser beams from the laser light source units of the second row are aligned in the height direction, a turning mirror configured to guide the first beam stack into the beam combiner, and a polarization converter.

According to an embodiment of the present disclosure, the submount may include a ceramic substrate made of a ceramic material, and an upper metal layer and a lower metal layer thermally bonded to upper and lower surfaces of the ceramic substrate, respectively, and the laser diode may be bonded to the upper metal layer.

According to an embodiment of the present disclosure, in the submount, the ceramic substrate may disperse heat transferred from the upper metal layer and transfer the heat to the lower metal layer, and the lower metal layer may perform heat dissipation through the cooler.

According to an embodiment of the present disclosure, the cooler may include a metal layer disposed on an uppermost layer thereof and formed of a heat conductive layer without a coolant channel, and a plurality of layers formed as metal layers or ceramic layers and attached to a lower portion of the uppermost layer while forming the coolant channel therein, and the coolant channel may include a coolant inlet hole and a coolant outlet hole, which are connected to the coolant flow path of the coolant housing unit, and a recessed region formed between the coolant inlet hole and the coolant outlet hole to correspond to a cooling region in which the laser diode is disposed, and in which coolant proceeds from downward to upward while taking heat transferred from the uppermost metal layer.

According to an embodiment of the present disclosure, the recessed region may include a lower recess, a bar-shaped rising channel formed with a cross-sectional area smaller than that of the lower recess, extending in a width direction of the cooler, and making a flow that causes the coolant to rise with an increasing flow rate, and an upper recess in which the coolant rising through the bar-shaped rising channel moves horizontally while taking heat, and is discharged through the coolant outlet hole. The upper recess may have a cross-sectional area greater than that of the coolant inlet hole.

According to an embodiment of the present disclosure, the upper recess may be formed in a fin-free structure. According to an embodiment of the present disclosure, the coolant outlet hole may be disposed to be spaced apart from the cooling region, the cooler may include a first channel in which the coolant rising through the coolant inlet hole is discharged through the upper recess, and a second channel connected to the first channel in a vertical direction and connected to the coolant outlet hole, and the second channel may be formed with the same width as the first channel and may have a thickness greater than that of the first channel.

According to an embodiment of the present disclosure, the cooler may be electrically insulated from the laser diode by the ceramic substrate, and the coolant flowing inside the cooler may be distilled water.

According to an embodiment of the present disclosure, the laser diode may be a single-emitter diode.

According to an embodiment of the present disclosure, the cooler may include a first side surface relatively away from the SAC lens and a second side surface relatively close to the SAC lens, and the submount may be bonding-coupled to the upper surface of the cooler toward the first side surface.

### BRIEF DESCRIPTION OF THE DRAWINGS

The above and other objects, features, and advantages of the present disclosure will become more apparent to those of ordinary skill in the art by describing exemplary embodiments thereof in detail with reference to the accompanying drawings, in which:

FIG. 1 is a plan view of a laser diode package according to an embodiment of the present disclosure;

FIG. 2 is a side view of the laser diode package according to the embodiment of the present disclosure;

FIG. 3 is a plan view of a laser light source unit of the laser diode package according to the embodiment of the present disclosure;

FIG. 4 is a side view of the laser light source unit according to one embodiment of the present disclosure;

FIG. 5 is a side view of a laser light source unit according to another embodiment of the present disclosure;

FIG. 6 is an exploded view of a cooler of the laser light source unit according to the embodiment of the present disclosure; and

FIG. 7 is a view for describing a coolant channel of the cooler of the laser light source unit according to the embodiment of the present disclosure.

### DETAILED DESCRIPTION OF EXEMPLARY EMBODIMENTS

Hereinafter, embodiments of the present disclosure will be described in detail with reference to the accompanying drawings. The embodiments illustrated below are not intended to limit the scope of the present disclosure and are provided to describe the present disclosure to one of ordinary skill in the art. In the drawings, like reference numerals refer to like components, and the size or thickness of each component may be exaggerated for clarity of description. In addition, when a certain material layer is described as being on a substrate or another layer, the material layer may be on the substrate or another layer by directly contacting the same, or a third layer may be present between the material layer, and the substrate or another layer.

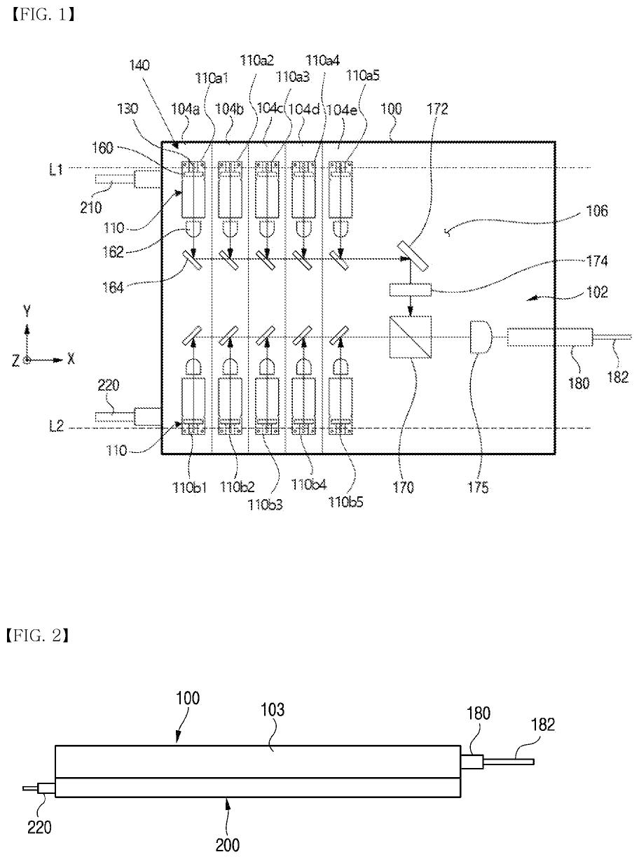

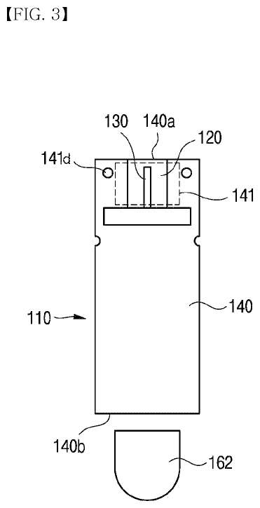

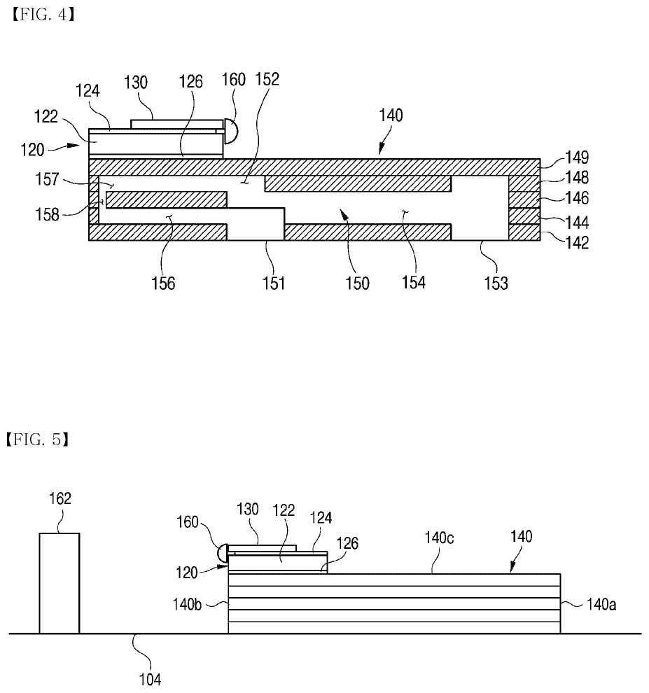

FIG. 1 is a plan view of a laser diode package according to an embodiment of the present disclosure, FIG. 2 is a side view of the laser diode package according to the embodiment of the present disclosure, FIG. 3 is a plan view of a laser light source unit of the laser diode package according to the embodiment of the present disclosure, and FIG. 4 is a side view of the laser light source unit according to one embodiment of the present disclosure.

Referring to FIGS. 1 and 2, the laser diode package includes laser light source units 110 each including a laser diode 130, a packaging housing unit 100 including optical elements for introducing laser beams emitted from the laser diodes into an optical fiber, and a coolant housing unit 200 provided on a lower surface of the packaging housing unit 100 and through which coolant is introduced and discharged.

The packaging housing unit 100 includes a base 102 and a side wall 103 and is covered by a cover (not shown). The packaging housing unit 100 includes the base 102, and the laser light source units 110 each including the laser diode 130, and optical elements such as collimating lenses 160 and 162, reflective mirrors 164, and a beam combiner 170, are disposed on the base 102.

The coolant housing unit 200 includes a coolant inlet 210 and a coolant outlet 220, and coolant introduced through the coolant inlet 210 is flowed into a cooler 140 of each of the laser light source units 110 to remove heat from the laser diode 130, and discharged through the coolant outlet 220. The coolant discharged through the coolant outlet 220 forms a circulating flow that flows through a chiller and is cooled again before being introduced into the coolant inlet 210.

The packaging housing unit 100 and the coolant housing unit 200 may be integrally formed.

The arrangement of the optical elements inside the packaging housing unit 100 will be described with reference to FIGS. 1 and 3.

The laser light source unit 110 includes the laser diode 130 on an upper surface thereof. The laser diode 130 is a single-emitter diode and is formed as a semiconductor chip. Each laser diode 130 emits a laser beam in a Y direction. A slow axis of each laser beam is parallel to an X-axis, and a fast axis thereof is parallel to a Z-axis.

The laser light source units 110 may be disposed in an X direction to be spaced apart from each other in a line along a side surface of the base 102 in the packaging housing unit 100. Reference numeral 110 is used to representatively designate the laser light source units.

According to the embodiment of the present disclosure, the laser light source units 110 may be disposed in two rows facing each other. Laser light source units 110a1, 110a2, 110a3, 110a4, and 110a5 of a first row L1 are disposed in the X direction along one side surface of the base, and laser light source units 110b1, 110b2, 110b3, 110b4, and 110b5 of a second row L2 are disposed in the X direction along the other side surface of the base.

The laser light source units 110a1, 110a2, 110a3, 110a4, and 110a5 of the first row L1 and the laser light source units 110b1, 110b2, 110b3, 110b4, and 110b5 of the second row L2 output laser beams in opposite directions in the Y direction on the base 102. The laser light source units 110b1, 110b2, 110b3, 110b4, and 110b5 of the first row L1 and the laser light source units 110b1, 110b2, 110b3, 110b4, and 110b5 of the second row L2 can output laser beams in directions toward each other in the Y direction.

The base 102 on which the laser light source units 110 are disposed includes a step-type surface 104 having a plurality of stepped surfaces 104a, 104b, 104c, 104d, and 104e. Adjacent stepped surfaces are vertically offset from each other, and the laser light source units of each of the rows L1 and L2 are disposed to correspond to the stepped surfaces 104a, 104b, 104c, 104d, and 104e, respectively.

For example, a first laser light source unit 110al of the first row belonging to the laser light source units of the first row L1 and a first laser light source unit 110b1 of the second row belonging to the laser light source units of the second row L2 may be disposed on a first stepped surface 104a to face each other, and a second laser light source unit 110a2 of the first row L1 and a second laser light source unit 110b2 of the second row L2 may be disposed on a second stepped surface 104b to face each other.

The laser light source unit 110b1, 110b2, 110b3, 110b4, or 110b5 of the first row L1 and the laser light source unit 110b1, 110b2, 110b3, 110b4, or 110b5 of the second row L2 are illustrated in the drawing as being disposed on one stepped surface to face each other such that optical paths thereof face each other, but may be disposed to be staggered from each other with an offset in a horizontal direction.

A fast-axis collimating (FAC) lens 160 and a slow-axis collimating (SAC) lens 162 are included to collimate the laser beam.

The laser beam is multi-mode in an X-axis direction with a relatively small divergence angle of approximately 8° to 12°. Among the laser beams emitted from the laser diode, the laser beam emitted in the Y direction is spatially single-mode, with a relatively large divergence angle of approximately 28° to 35°. The laser beams emitted from the laser diode 130 has different divergence angles depending on the direction, and thus a collimating lense for each direction is required to make the laser beam emitted from the laser diode 130 into parallel light.

The FAC lens 160 is installed adjacent to a front side of the laser diode 130 to collimate the laser beam in a fast axis direction, and the SAC lens 162 is installed at a front side of the FAC lens 160 in a laser beam traveling direction to collimate the laser beam in a slow axis direction.

The FAC lens 160 and the SAC lens 162 are sequentially installed at a front side of the laser light source unit 110 in a laser beam emission direction. The FAC lens 160 may be disposed adjacent to a laser beam emission surface of the laser diode 130, and the SAC lens 162 may be disposed on each of the stepped surfaces 104a, 104b, 104c, 104d, and 104e, on which the laser light source units 110 are respectively disposed, in the laser beam emission direction.

Referring to FIG. 3, the laser light source unit 110 includes the cooler 140, a submount 120, and the laser diode 130.

The cooler 140 includes a first side surface 140a and a second side surface 140b, which are opposite to each other, and an upper surface 140c. The first side surface 140a is defined as a side surface away from the SAC lens 162, and the second side surface 140b is defined as a side surface relatively closer to the SAC lens 162 than the first side surface 140a, i.e., a side surface facing the first side surface 140a.

The laser diode 130 is disposed on the upper surface 140c of the cooler 140 in the form of a chip on submount (CoS) mounted on the submount 120, and referring to FIG. 3, the submount 120 is disposed on the upper surface 140c of the cooler 140 at the first side surface 140a side. The FAC lens 160 may be fixed to a front surface of the submount 120 on the upper surface 140c of the cooler 140. In addition, the FAC lens 160 may be fixed to the front surface side (laser beam emission direction) of the submount 120. Since the SAC lens 162 is disposed adjacent to the second side surface 140b of the cooler 140, it is possible to downsizing the laser diode package.

Referring to FIG. 4, the submount 120 is fixed to the upper surface 140c of the cooler 140 in a direction of the second side surface 140b. The SAC lens 162 is disposed at a position spaced apart from the second side surface 140b of the cooler 140. FIG. 4 illustrates the FAC lens 160 in a form that is integral to the submount 120, i.e., integral to the CoS. The FAC lens 160 may be disposed on the stepped surface 104 adjacent to the laser light source unit 110.

The FAC lens 160 and the SAC lens 162 may be collectively referred to as a collimating lens, and the collimating lens for collimating the laser beam is not limited to the FAC lens and the SAC lens of the arrangement described above, but various collimating optics may be used as the collimating lens.

Referring to FIG. 1 again, a reflective mirror 164 for redirecting the laser beam emitted from each laser diode 130 is disposed on each of the stepped surfaces 104a and 104b.

The reflective mirror 164 reflects the collimated laser beam into a region in which the beam combiner 170 is located. The base 102 includes the step-type surface 104 that gradually decreases in height towards an optical elements arrangement region 106 in which the beam combiner 170 is located. The optical elements arrangement region 106 is a beam combining region on which the laser beams emitted from the laser diodes 130 are combined by optical elements.

Referring to the drawings, each laser beam in the first row L1 proceeds in the −Y direction and is reflected by the corresponding reflective mirror 164 and proceeds in the X direction (+X) towards the optical elements arrangement region 106 in which the beam combiner 170 is located, and each laser beam in the second row L2 proceeds in the +Y direction of and is reflected by the corresponding reflective mirror 164 and then proceeds in the X direction (+X) towards the optical elements arrangement region 106. A path in which each laser beam in the first row L1 is reflected and proceeds toward the beam combining region and a path in which each laser beam in the second row L2 is reflected and proceeds toward the beam combining region are parallel to each other.

Due to a vertical offset between the stepped surfaces 104a and 104b, the laser beam reflected by the reflective mirror 164, which is located relatively far from the optical elements arrangement region 106, proceeds to an upper side of the reflective mirror 164, which is located adjacent to the reflective mirror 164 that has reflected the laser beam and relatively close to the optical elements arrangement region 106. Thus, the laser beams may be spatially stacked.

The laser beams of each of the first row L1 and the second row L2 are stacked in a Z direction to form a first beam stack and a second beam stack, respectively, and formed into one stacked beam, that is, a stacked beam, in the beam combiner 170.

The beam combiner 170 may include a polarization beam combiner. The first beam stack of the stacked laser beams of the first row L1 is reflected by a turning mirror 172, is changed in polarization direction while passing through a polarization converter 174, and is input to the beam combiner 170. In addition, the second beam stack of the stacked laser beams of the second row L2 is directly input to the polarization beam combiner 170. The first beam stack and the second beam stack are combined in the polarization beam combiner 170 to form the stacked beam.

The stacked beam emitted from the polarization beam combiner 170 may be coupled to an optical fiber 182 through a coupling lens 175. The optical fiber 182 is coupled to the side wall 103 of the packaging housing unit 100 by an optical fiber holder 180.

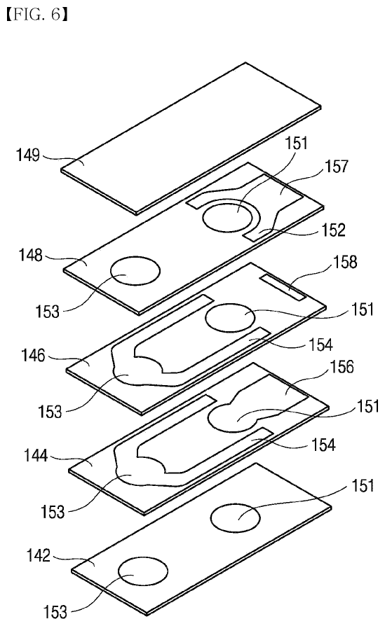

A mounting structure of the laser diode 130 of the laser light source unit 110 will be described with reference to FIGS. 3 and 5. FIGS. 4 and 5 are side views of the laser light sources illustrated according to another embodiment.

A laser light source unit 110 includes a cooler 140, a submount 120, and a laser diode 130, and the laser diode 130 is bonded to an upper surface of the submount 120 by soldering.

The submount 120 includes a ceramic substrate 122, such as aluminum nitride (AlN) or beryllium oxide (BeO), and an upper metal layer 124 and a lower metal layer 126 thermally bonded to upper and lower surfaces of the ceramic substrate 122, respectively. The ceramic substrate 122 of the submount 120 has an high thermal conductivity coefficient and thus diffuses and disperses heat generated from the laser diode 130 and transfers the heat to the cooler 140.

According to the embodiment of the present disclosure, the lower metal layer 126 is made of a material that has a thermal expansion coefficient similar or identical to that of the cooler. According to the embodiment of the present disclosure, the uppermost layer of the upper metal layer 124, the lower metal layer 126, and the cooler 140 is formed of a copper material. The upper metal layer 124 receives heat from the laser diode 130, and the lower metal layer 126 transfers the heat of the ceramic substrate 122 to the cooler 140. The heat transferred from the upper metal layer 124 of the ceramic substrate 122 is diffused and dispersed to be transferred to the lower metal layer 126.

The submount 120 is bonded to a cooling region 141 of the cooler 140 by soldering. The cooling area 141 corresponds to a recessed region of the cooler 140.

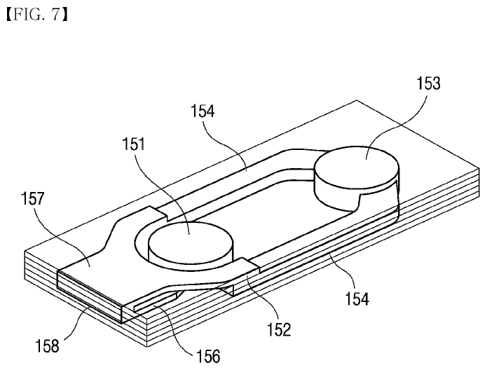

The cooler of the laser light source unit will be described with reference to FIGS. 3 to 7. FIG. 6 is an exploded view of the cooler of the laser light source unit according to the embodiment of the present disclosure, and FIG. 7 is a view for describing a coolant channel of the cooler of the laser light source unit according to the embodiment of the present disclosure.

According to the embodiment of the present disclosure, the cooler 140 is formed of a plurality of layers. According to the embodiment of the present disclosure, the cooler 140 is formed by bonding five layers 142, 144, 146, 148, and 149. Each layer may be formed as a metal layer or a ceramic layer, wherein the metal layer may be formed of a copper material, and the ceramic layer may be formed of AlN.

At least the uppermost layer of the cooler 140 is formed as a metal layer, e.g., a copper material. Accordingly, the cooler 140 can be bonding-coupled to the lower metal layer 126 of the submount 120.

Hereinafter, an example in which each layer of the cooler 140 is formed as a metal layer will be described.

The cooler 140 is provided with a mounting hole 144d (see FIG. 3) into which a mounting pin (not shown) is inserted, and is positionally fixed to the base 102 using the mounting pin. As shown in FIGS. 4 to 7, a coolant channel 150, through which coolant flows, is formed inside the cooler 140. In FIGS. 4 to 7, the mounting hole is omitted.

The coolant channel 150 includes a coolant inlet hole 151 and a coolant outlet hole 153, and includes a recessed region formed at a position corresponding to the cooling region 141, and a first channel 152 and a second channel 154 that connect the recessed region and the coolant outlet hole 153.

The recessed region includes a lower recess 156, an upper recess 157, and a bar-shaped rising channel 158 connecting the upper recess 157 and the lower recess 156.

When describing the arrangement relationship of each metal layer in the coolant channel 150, the coolant inlet hole 151 and the coolant outlet hole 153 are formed in a first metal layer 142, which forms the lowermost layer, to be spaced apart from each other. The coolant inlet hole 151 is adjacent to the cooling area 141 as compared with the coolant outlet hole 153.

A second metal layer 144 is bonded to an upper portion of the first metal layer 142. In the second metal layer 144, the coolant inlet hole 151 and the coolant outlet hole 153 are formed. The lower recess 156 connected to the coolant inlet hole 151 is formed and the second channel 154 connected to the coolant outlet hole 153 is formed. Coolant flows to the coolant outlet hole 153 through the second channel 154.

A third metal layer 146 is bonded to an upper portion of the second metal layer 144, and the coolant inlet hole 151 and the coolant outlet hole 153 are formed in the third metal layer 146. The bar-shaped rising channel 158 is formed in the third metal layer 146 at a position corresponding to an end portion of the cooling region 141. The bar-shaped rising channel 158 forms a coolant path between the lower recess 156 and the upper recess 157, and increases the flow rate of the coolant flowing in the upper recess 157 to improve cooling efficiency.

The coolant inlet hole 151 of the third metal layer 146 is in communication with the coolant inlet hole 151 of a fourth metal layer 148. An upper end of the coolant inlet hole 151 of the fourth metal layer 148 is blocked by a fifth metal layer 149. That is, the coolant introduced into the coolant inlet hole 151 flows to the lower recess 156 and simultaneously cools the fifth metal layer 149.

The fourth metal layer 148 is bonded to an upper portion of the third metal layer 146. In the fourth metal layer 148, the coolant inlet hole 151 and the coolant outlet hole 153 are formed. The first channel 152 spaced apart from the coolant inlet hole 151 is formed. The first channel 152 is connected to the upper recess 157 to form a path through which the coolant is discharged to the second channel 154, and the first channel 152 and the second channel 154 have channel end portions that partially overlap in a vertical direction. Thus, the coolant can flow from the first channel 152 to the second channel 154. The first channel 152 surrounds the coolant inlet hole 151 in an arc or semicircular shape and extends to be spaced apart therefrom.

Since the second channel 154 is formed of two layers and the first channel 152 is formed of one layer, the second channel 154 is formed twice as thick as the first channel 152. When the second channel 154 is formed with a thickness greater than that of the first channel 152 and the second channel 154 and the first channel 152 are formed with the same or similar width, a fast coolant flow is induced in the upper recess 157. In the fourth metal layer 148, the coolant outlet hole 153 has a structure whose upper end is blocked by the fifth metal layer 149, and cools the fifth metal layer 149.

The fifth metal layer 149 forms a heat conductive plate through which the coolant flowing along the coolant channel 150 takes heat away from the lower metal layer, and the upper surface of the fifth metal layer 149 is formed as an upper surface of the cooler and forms a bonding surface to which the submount 120 is bonded. The fifth metal layer 149 forms the uppermost layer of the cooler 140 and is a heat conductive layer without having the coolant channel 150.

By such an arrangement of the coolant channel 150 inside the cooler 140, the coolant introduced through the coolant inlet hole 151 rises, is introduced into the lower recess 156, rises at an increased flow rate through the bar-shaped rising channel 158 from the lower recess 156, and then absorbs heat in the upper recess 157. The coolant in the upper recess 157 is guided to the coolant outlet hole 153 with a fast flow due to the difference in cross-sectional area between the first channel 152 and the second channel 154. In addition, the coolant inlet hole 151 and the coolant outlet hole 153 are in contact with and cool the uppermost layer of the cooler.

The coolant flow path increases the cooling efficiency of the cooler 140 and improves the performance of absorbing heat from the cooling region 141. That is, the cooler 140 receives and cools heat in the form of being diffused and dispersed by the submount 120, and thus can have excellent heat removal efficiency by being used together with the submount 120.

The cooler 140 may have a length that is at least twice as long as that of the submount 120, and a width of the cooler 140 may be 1.5 to 3 times as large as a width of the submount 120. The width of the submount 120 may be formed to be less than a width of the upper recess 157. Although the ceramic substrate has a thermal conductivity coefficient with a smaller value than a metal, for example, a copper material, which is the material of the cooler, the submount 120 including the ceramic substrate can achieve sufficient heat dissipation by diffusing heat and transferring the heat to the cooler 140. Furthermore, the coolant flow path of the cooler 140 according to the embodiment of the present disclosure is designed to effectively absorb and dissipate heat dispersed in the ceramic substrate 122 of the submount 120.

The heat dissipation structure in which the submount 120 diffuses heat generated by the laser diode 130 and transfers the heat to the cooler 140 as in the embodiment of the present disclosure allows a channel width of the coolant channel of the cooler 140 to be increased. According to the embodiment of the present disclosure, the channel width of each of the first and second channels may have a value that is 28 times larger than a channel width of a conventional micro-cooling channel.

In addition, the coolant channel 150 according to the present disclosure is formed in a fin-free structure that does not have a web- or fin-shaped structure. Since the submount 120 diffuses heat and transfers the heat to the cooler 140, the heat is not concentrated and the web- or fin-shaped structure can be omitted. In a conventional microchannel type, a width of a minimum flow path is small and a web-shaped structure is provided, which causes problems with pipe blockage when foreign substances are present in the coolant. When the coolant channel flow path is partially blocked, cooling performance is degraded. This causes the laser diode to overheat, damaging the chip and reducing the output. However, according to the present disclosure, the width of the coolant channel is greatly increased to prevent blockage of the channel by foreign substances and a decrease in flow rate, while preventing the cooling performance from decreasing by diffusing and transferring the heat through the submount 120.

Further, according to the present disclosure, the laser diode 130 can be electrically insulated from the cooler 140 formed of a metal material. The electrical insulation is achieved by the submount 120 including the ceramic substrate 122 interposed between the laser diode 130 and the cooler 140.

When the laser diode 130 and the cooler 140, which is made of a metal material, are directly bonded, deionized water must be used as the coolant for electrical insulation. However, the deionized water is highly corrosive and causes other problems such as the generation of foreign substances. However, according to the embodiment of the present disclosure, since electrical insulation is achieved by self-insulation of the submount 120, distilled water rather than deionized water can be used. Thus, the effect of pipe blockage caused by corrosion can be minimized.

The present disclosure enables a plurality of laser diodes to be packaged in a compact form within a laser diode package. Accordingly, the output of a laser beam of the laser diode package can be easily increased.

In a laser diode package of the present disclosure, heat generated from a single-emitter diode configured to output a laser beam can be effectively removed. Accordingly, even when pumping power increases, an output degradation problem does not occur.

According to the present disclosure, a coolant channel of a cooler can be formed in a structure that can be prevented from being blocked by foreign substances, so that the possibility of a coolant flow failure and associated performance degradation can be minimized.

According to the present disclosure, distilled water can be used as coolant, so that the occurrence of foreign substances in the process of flowing the coolant can be minimized.

Although the embodiments of the present disclosure have been described above, it is to be understood that the embodiments are merely illustrative, and various modifications and other equivalent embodiments are possible therefrom by those skilled in the art.

What is claimed is:

1. A laser diode package comprising:
a packaging housing unit;
a coolant housing unit that is coupled to the packaging housing unit, includes a coolant inlet through which coolant is introduced and a coolant outlet through which the coolant is discharged, and has a coolant flow path therein; and
laser light source units each including a laser diode configured to emit a laser beam, collimating lenses each configured to collimate the laser beam emitted from the laser light source unit, reflective mirrors each configured to reflect the collimated laser beam to an optical element arrangement region on a base, and an optical fiber provided in the optical element arrangement region and in which a stacked beam formed by gathering each laser beam is coupled and emitted to the outside, which are disposed on the base of the packaging housing unit,
wherein the laser light source unit includes:
a cooler coupled to the base, including a coolant channel connected to the coolant flow path of the coolant housing unit, and having at least an upper surface made of a metal layer; and
a submount bonding-coupled to the upper surface of the cooler and having an upper surface to which the laser diode is bonding-coupled.

2. The laser diode package of claim 1, wherein the base of the packaging housing unit is divided into a step-type surface having a plurality of stepped surfaces, and the optical element arrangement region formed at one side of the step-type surface,
the laser light source units are disposed on the stepped surfaces of the step-type surface, respectively, in a direction facing each other, and include laser light source units disposed along one side surface of the base to form a first row and laser light source units disposed along the other side surface of the base to form a second row,
in a space between the laser light source unit of the first row and the laser light source unit of the second row, a slow-axis collimating (SAC) lens for collimating the laser beam emitted from each laser light source unit and the reflective mirror are installed in each stepped surface, and
the optical element arrangement region includes a beam combiner configured to combine a first beam stack, in which laser beams from the laser light source units of the first row are aligned in a height direction, and a second beam stack, in which laser beams from the laser light source units of the second row are aligned in the height direction, a turning mirror configured to guide the first beam stack into the beam combiner, and a polarization converter.

3. The laser diode package of claim 1, wherein the submount includes a ceramic substrate made of a ceramic material, and an upper metal layer and a lower metal layer thermally bonded to upper and lower surfaces of the ceramic substrate, respectively, and
the laser diode is bonded to the upper metal layer.

4. The laser diode package of claim 3, wherein in the submount, the ceramic substrate disperses heat transferred from the upper metal layer and transfers the heat to the lower metal layer, and
the lower metal layer performs heat dissipation through the cooler.

5. The laser diode package of claim 4, wherein the cooler includes a metal layer disposed on an uppermost layer thereof and formed of a heat conductive layer without a coolant channel, and a plurality of layers formed as metal layers or ceramic layers and attached to a lower portion of the uppermost layer while forming the coolant channel therein, and
the coolant channel includes a coolant inlet hole and a coolant outlet hole, which are connected to the coolant flow path of the coolant housing unit, and a recessed region formed between the coolant inlet hole and the coolant outlet hole to correspond to a cooling region in which the laser diode is disposed, and in which coolant proceeds from downward to upward while taking heat transferred from the uppermost metal layer.

6. The laser diode package of claim 5, wherein the recessed region includes:
a lower recess;
a bar-shaped rising channel formed with a cross-sectional area smaller than that of the lower recess, extending in a width direction of the cooler, and making a flow that causes the coolant to rise with an increasing flow rate; and
an upper recess in which the coolant rising through the bar-shaped rising channel moves horizontally while taking heat, and is discharged through the coolant outlet hole.

7. The laser diode package of claim 6, wherein the upper recess is formed in a fin-free structure.

8. The laser diode package of claim 6, wherein the coolant outlet hole is disposed to be spaced apart from the cooling region,
the cooler includes a first channel in which the coolant rising through the coolant inlet hole is discharged through the upper recess, and a second channel connected to the first channel in a vertical direction and connected to the coolant outlet hole, and
the second channel is formed with the same width as the first channel and has a thickness greater than that of the first channel.

9. The laser diode package of claim 1, wherein the cooler is electrically insulated from the laser diode by the ceramic substrate, and
the coolant flowing inside the cooler is distilled water.

10. The laser diode package of claim 1, wherein the laser diode is a single-emitter diode.

11. The laser diode package of claim 2, wherein the cooler includes a first side surface relatively away from the SAC lens and a second side surface relatively close to the SAC lens, and
the submount is bonding-coupled to the upper surface of the cooler toward the first side surface.
